(19) United States
(12) Patent Application Publication
(10) Pub. No.: US 2009/0323285 A1
(43) Pub. Date: Dec. 31, 2009

(54) HEAT TRANSPORT DEVICE AND ELECTRONIC APPARATUS

(75) Inventors: Hiroyuki RYOSON, Kanagawa (JP); Takashi YAJIMA, Tokyo (JP); Mitsuo HASHIMOTO, Kanagawa (JP); Toshiro OOTA, Kanagawa (JP); Tatsuhiko SHIGEMOTO, Tokyo (JP); Kazuo GOTO, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: Sony Corporation, Tokyo (JP)

(21) Appl. No.: 12/489,701

(22) Filed: Jun. 23, 2009

(30) Foreign Application Priority Data
Jun. 25, 2008 (JP) 2008-165352

(51) Int. Cl. H05K 7/20; F28D 15/02

(52) U.S. Cl. 361/700; 165/104.26

(57) ABSTRACT

A heat transport device includes an airtight container, a working fluid contained in the airtight container, and a plurality of plate-like members including a first plate-like member and a second plate-like member adjacent to the first plate-like member, the plate-like members each having a first hole having a first opening area and a second hole having a second opening area smaller than the first opening area, the plate-like members being layered in the airtight container so that the first hole of the first plate-like member and the first hole of the second plate-like member are communicated with each other, to retain the working fluid in a liquid phase by applying a capillary force to the working fluid, and so that an opening of the second hole is located within an opening of the first hole, to transfer the working fluid vaporized into a gas phase in the layered direction.

### BACKGROUND OF THE INVENTION

1. Field of the Invention

The present invention relates to a heat transport device to transport heat by a phase transition of a working fluid, and to an electronic apparatus including the heat transport device mounted thereon.

2. Description of the Related Art

To cool an electronic apparatus such as a personal computer, a heat transport device such as a heat pipe that transports heat generated in a heat generation portion of the electronic apparatus to a condensation portion and radiates the generated heat is used. In a heat pipe, a gas-phase working fluid vaporized by heat generated in a high-temperature heat generation portion of an electronic apparatus is moved to a low-temperature condensation portion and condensed into a liquid by the condensation portion. Then, heat is released, thereby cooling a heat generator.

Along with reduction in thickness of an electronic apparatus, it is desirable to reduce the thickness of such a heat pipe. For example, there has been proposed a heat pipe in which several partition plates constituted of thin plates having slits are layered and sealed in a container and a working fluid is contained in the container (see, for example, Japanese Patent Application Laid-open No. 2002-39693 (paragraph 0015, FIGS. 1 and 2)). In this heat pipe, the multiple partition plates are layered so that the slits of the partition plates are set to be out of alignment in a width direction. With this structure, a portion that passes through slits functions as a flow path of a vaporized working fluid, and a portion at which slits are not aligned functions as a transfer path through which a condensed working fluid is moved by a capillary action.

### SUMMARY OF THE INVENTION

However, the heat pipe mentioned above makes it difficult to perform a process of making slits at a low cost. In addition, thin plates that have been processed into slits are difficult to be handled. For these reasons, there is a problem in that mass production of the above-mentioned heat pipe is difficult.

In view of the above-mentioned circumstances, it is desirable to provide a heat transport device capable of being easily processed and stably mass-produced, and provide an electronic apparatus including the heat transport device mounted thereon.

According to an embodiment of the present invention, there is provided a heat transport device. The heat transport device includes an airtight container, a working fluid contained in the airtight container, and a plurality of plate-like members. The plurality of plate-like members include a first plate-like member and a second plate-like member adjacent to the first plate-like member, the plurality of plate-like members each having a first hole having a first opening area and a second hole having a second opening area smaller than the first opening area, the plurality of plate-like members being layered in the airtight container so that the first hole of the first plate-like member and the first hole of the second plate-like member are communicated with each other, to retain the working fluid in a liquid phase by applying a capillary force to the working fluid, and so that an opening of the second hole of the second plate-like member is located within an opening of the first hole of the first plate-like member, to transfer the working fluid vaporized into a gas phase in the layered direction.

In the embodiment, by causing the first holes formed in the first plate-like members and the second plate-like members adjacent to each other to be communicated with each other, the flow path of the liquid-phase working fluid can be obtained. By locating the openings of the second holes of the second plate-like member within the openings of the first holes of the first plate-like member, the flow path of the gas-phase working fluid can be obtained in the layered direction. In addition, the plate-like members having the holes are layered to thereby generate the capillary force, and thus the working fluid can be circulated in the airtight container in conjunction with the capillary action and a vaporization phenomenon. Accordingly, in a case where a heat generation member is provided adjacently to the heat transport device, heat generated from the heat generation member can be transported extensively in an in-plane direction of the heat transport device and radiated. The plate-like members having the holes can be manufactured by a punching process using a pin, for example. As a result, the plate-like members can be easily manufactured as compared to a case where a slit process is used. In addition, the plate-like members having the holes are easily handled as compared to plate-like members having the slits, and therefore can be stably mass-produced.

Further, the heat transport device includes a bottom plate and an upper plate that constitute the airtight container and are provided to sandwich the plurality of plate-like members. The upper plate has a protrusion that protrudes toward the plurality of plate-like members.

With this structure in which the protrusion is provided on the upper plate, the heat transport device having excellent pressure resistance can be obtained. In other words, when the heat transport device is used, an inner pressure thereof is reduced in general. By providing the protrusion, even when the thickness of the upper plate is reduced for reduction in thickness of the heat transport device, the heat transport device can be prevented from being dented by an outer pressure. In addition, the heat transport device is connected with a heat sink by soldering in general. In this case, the heat transport device and the heat sink are set into a high-temperature furnace, and solder is melted to connect them in many cases. At this time, a temperature of the heat transport device is sometimes increased to 200° C. or more, and a vapor pressure of the working fluid therein is significantly increased. Therefore, a pressure is applied from inside toward outside. However, by providing the protrusion, the pressure resistance is improved as compared to a case where the protrusion is not provided. As a result, the heat transport device of high quality can be obtained.

The bottom plate has a groove on a surface on a side on which the plurality of plate-like members are provided.

With this structure in which the groove is formed in the bottom plate, a flow-path resistance of the liquid-phase working fluid can be reduced.

According to another embodiment, there is provided a heat transport device. The heat transport device includes an airtight container, a working fluid contained in the airtight container, and a plurality of plate-like members. The plurality of plate-like members include first plate-like members each having a first hole having a first opening area and second plate-like members each having a second hole having a second opening area smaller than the first opening area, the plurality of plate-like members being layered in the airtight container so that the first holes of the first plate-like members adjacent to each other are communicated with each other, to retain the working fluid in a liquid phase by applying a capillary force to the working fluid, and so that an opening of the second hole of each of the second plate-like members is located within an opening of the first hole of each of the first plate-like members, to transfer the working fluid vaporized into a gas phase in the layered direction.

In the embodiment, by causing the first holes formed in the adjacent first plate-like members to be communicated with each other, the flow path of the liquid-phase working fluid can be obtained. By locating the openings of the second holes of the second plate-like members within the openings of the first holes of the first plate-like members, the flow path of the gas-phase working fluid can be obtained in the layered direction. In addition, the plate-like members having the holes are layered to thereby generate the capillary force, and thus the working fluid can be circulated in the airtight container in conjunction with the capillary action and a vaporization phenomenon. Accordingly, in a case where a heat generation member is provided adjacently to the heat transport device, heat generated from the heat generation member can be transported extensively in an in-plane direction of the heat transport device and radiated. The plate-like members having the holes can be manufactured by a punching process using a pin, for example. As a result, the plate-like members can be easily manufactured as compared to a case where a slit process is used. In addition, the plate-like members having the holes are easily handled as compared to plate-like members having the slits, and therefore can be stably mass-produced.

According to another embodiment, there is provided a heat transport device. The heat transport device includes a working fluid, a plurality of plate-like members, and a first outer wall member and a second outer wall. The plurality of plate-like members include a first plate-like member and a second plate-like member adjacent to the first plate-like member, the plurality of plate-like members each having a first hole having a first opening area and a second hole having a second opening area smaller than the first opening area, the plurality of plate-like members being layered in the airtight container so that the first hole of the first plate-like member and the first hole of the second plate-like member are communicated with each other, to retain the working fluid in a liquid phase by applying a capillary force to the working fluid, and so that an opening of the second hole of the second plate-like member is located within an opening of the first hole of the first plate-like member, to transfer the working fluid vaporized into a gas phase in the layered direction. The first outer wall member and the second outer wall member are provided to sandwich the plurality of plate-like members in the layered direction of the plurality of plate-like members.

In the embodiment, by causing the first holes formed in the first plate-like members and the second plate-like members adjacent to each other to be communicated with each other, the flow path of the liquid-phase working fluid can be obtained. By locating the openings of the second holes of the second plate-like member within the openings of the first holes of the first plate-like member, the flow path of the gas-phase working fluid can be obtained in the layered direction. In addition, the plate-like members having the holes are layered to thereby generate the capillary force, and thus the working fluid can be circulated in the airtight container in conjunction with the capillary action and a vaporization phenomenon. Accordingly, in a case where a heat generation member is provided adjacently to the heat transport device, heat generated from the heat generation member can be transported extensively in an in-plane direction of the heat transport device and radiated. The plate-like members having the holes can be manufactured by a punching process using a pin, for example. As a result, the plate-like members can be easily manufactured as compared to a case where a slit process is used. In addition, the plate-like members having the holes are easily handled as compared to plate-like members having the slits, and therefore can be stably mass-produced.

According to another embodiment, there is provided a heat transport device. The heat transport device includes a working fluid, a plurality of plate-like members, and a first outer wall member and a second outer wall member. The plurality of plate-like members include first plate-like members each having a first hole having a first opening area and second plate-like members each having a second hole having a second opening area smaller than the first opening area, the plurality of plate-like members being layered so that the first holes of the first plate-like members adjacent to each other are communicated with each other, to retain the working fluid in a liquid phase by applying a capillary force to the working fluid, and so that an opening of the second hole of each of the second plate-like members is located within an opening of the first hole of each of the first plate-like members, to transfer the working fluid vaporized into a gas phase in the layered direction. The first outer wall member and the second outer wall member are provided to sandwich the plurality of plate-like members in the layered direction of the plurality of plate-like members.

In the embodiment, by causing the first holes formed in the adjacent first plate-like members to be communicated with each other, the flow path of the liquid-phase working fluid can be obtained. By locating the openings of the second holes of the second plate-like members within the openings of the first holes of the first plate-like members, the flow path of the gas-phase working fluid can be obtained in the layered direction. In addition, the plate-like members having the holes are layered to thereby generate the capillary force, and thus the working fluid can be circulated in the airtight container in conjunction with the capillary action and a vaporization phenomenon. Accordingly, in a case where a heat generation member is provided adjacently to the heat transport device, heat generated from the heat generation member can be transported extensively in an in-plane direction of the heat transport device and radiated. The plate-like members having the holes can be manufactured by a punching process using a pin, for example. As a result, the plate-like members can be easily manufactured as compared to a case where a slit process is used. In addition, the plate-like members having the holes are easily handled as compared to plate-like members having the slits, and therefore can be stably mass-produced.

According to another embodiment, there is provided an electronic apparatus. The electronic apparatus includes a heat generation member and a heat transport device disposed adjacently to the heat generation member. The heat transport device includes an airtight container, a working fluid contained in the airtight container, and a plurality of plate-like members including a first plate-like member and a second plate-like member adjacent to the first plate-like member, the plurality of plate-like members each having a first hole having a first opening area and a second hole having a second opening area smaller than the first opening area, the plurality of plate-like members being layered in the airtight container so that the first hole of the first plate-like member and the first hole of the second plate-like member are communicated with each other, to retain the working fluid in a liquid phase by applying a capillary force to the working fluid, and so that an opening of the second hole of the second plate-like member is located within an opening of the first hole of the first plate-like member, to transfer the working fluid vaporized into a gas phase in the layered direction.

In the heat transport device disposed adjacently to the heat generation member of the electronic apparatus in the embodiment, by causing the first holes formed in the first plate-like members and the second plate-like members adjacent to each other to be communicated with each other, the flow path of the liquid-phase working fluid can be obtained. By locating the openings of the second holes of the second plate-like member within the openings of the first holes of the first plate-like member, the flow path of the gas-phase working fluid can be obtained in the layered direction. In addition, the plate-like members having the holes are layered to thereby generate the capillary force, and thus the working fluid can be circulated in the airtight container in conjunction with the capillary action and a vaporization phenomenon. Accordingly, in the electronic apparatus of this embodiment, by providing the heat transport device, heat generated from the heat generation member can be transported extensively in an in-plane direction of the heat transport device and radiated. As a result, the electronic apparatus can be prevented from locally generating heat.

As described above, according to the embodiments, the heat transport device capable of being easily and stably mass-produced and the electronic apparatus including the heat transport device mounted thereon can be provided.

These and other objects, features and advantages of the present invention will become more apparent in light of the following detailed description of best mode embodiments thereof, as illustrated in the accompanying drawings.

### BRIEF DESCRIPTION OF DRAWINGS

FIG. 1 is an exploded perspective view schematically showing a heat pipe;

FIG. 2 is a schematic diagram for explaining an operation of the heat pipe shown in FIG. 1;

FIG. 3 is a plan view schematically showing a thin plate as a plate-like member that constitutes a part of the heat pipe shown in FIG. 1;

FIG. 4 is an enlarged plan view showing an area circled by the circle A of FIG. 3;

FIG. 5 is a plan view for explaining a positional relationship among holes of a plurality of thin plates;

FIG. 6 is a partial perspective view of the plurality of thin plates layered;

FIG. 7 is a cross-sectional view of the thin plates taken along the line B-B′ of FIG. 6;

FIG. 8A is a schematic plan view showing a positional relationship among holes of layered thin plates in an embodiment, and FIG. 8B is a schematic plan view showing a positional relationship among holes in a case where a plurality of thin plates into which the holes having the same size are formed are layered as a comparative example;

FIG. 9 is a plan view of an upper plate that constitutes a part of the heat pipe shown in FIG. 1;

FIG. 10 is a perspective view of a bottom plate that constitutes a part of the heat pipe shown in FIG. 1;

FIG. 11 is a schematic plan view showing thin plates as a modified example;

FIG. 12 is a diagram showing a positional relationship among holes when the thin plates shown in FIG. 11 are layered;

FIG. 13 is a schematic plan view showing thin plates as another modified example;

FIG. 14 is a graph showing a relationship between the depth of grooves of the bottom plate and a heat transport amount;

FIG. 15A is a schematic perspective view of a personal computer, and FIG. 15B is a plan view showing a partial structure of the personal computer shown in FIG. 15A;

FIG. 16 is a schematic plan view of a liquid crystal television;

FIG. 17 is a diagram for explaining a capillary structure in the embodiment; and

FIG. 18 is a diagram for explaining the capillary structure.

### DESCRIPTION OF PREFERRED EMBODIMENTS

(Heat Transport Device)

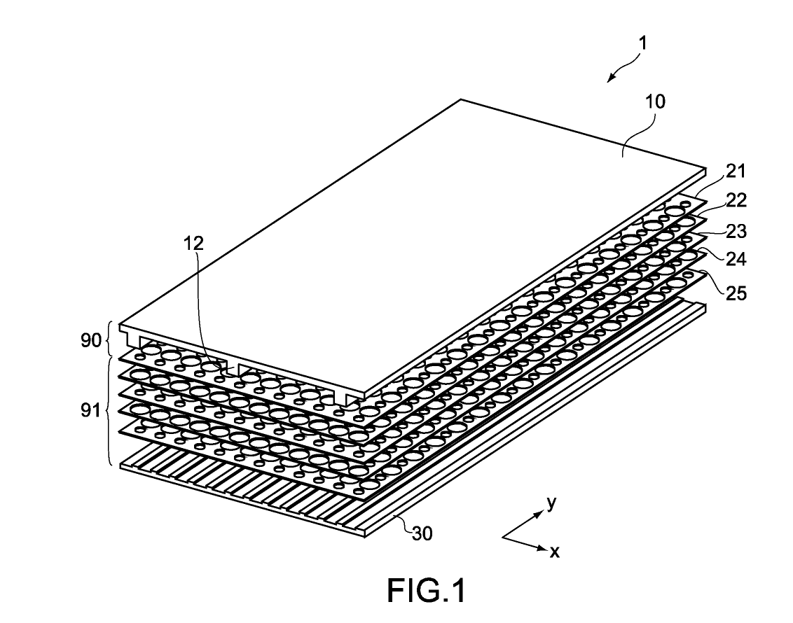

Hereinafter, an embodiment of the present invention will be described with reference to FIGS. 1 to 10 and 17. To facilitate visualization of the figures, the number of components such as thin plates and holes is reduced, and scale ratios of structures are set to be different unlike actual structures.

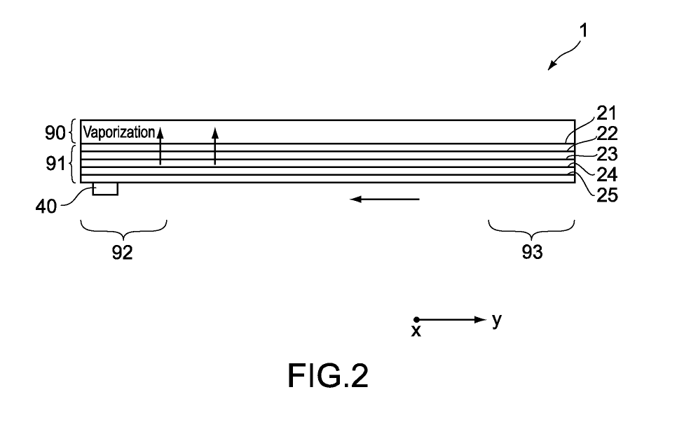

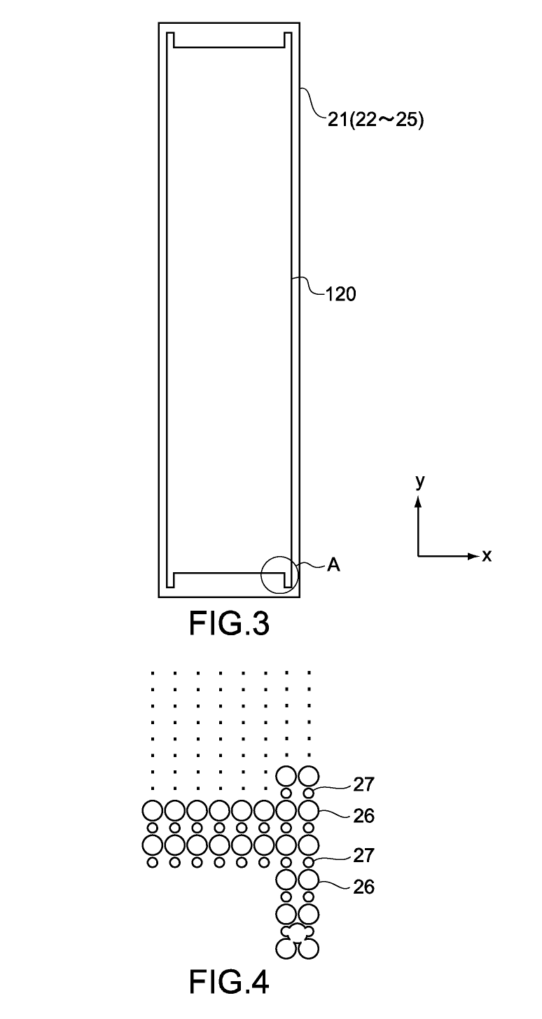

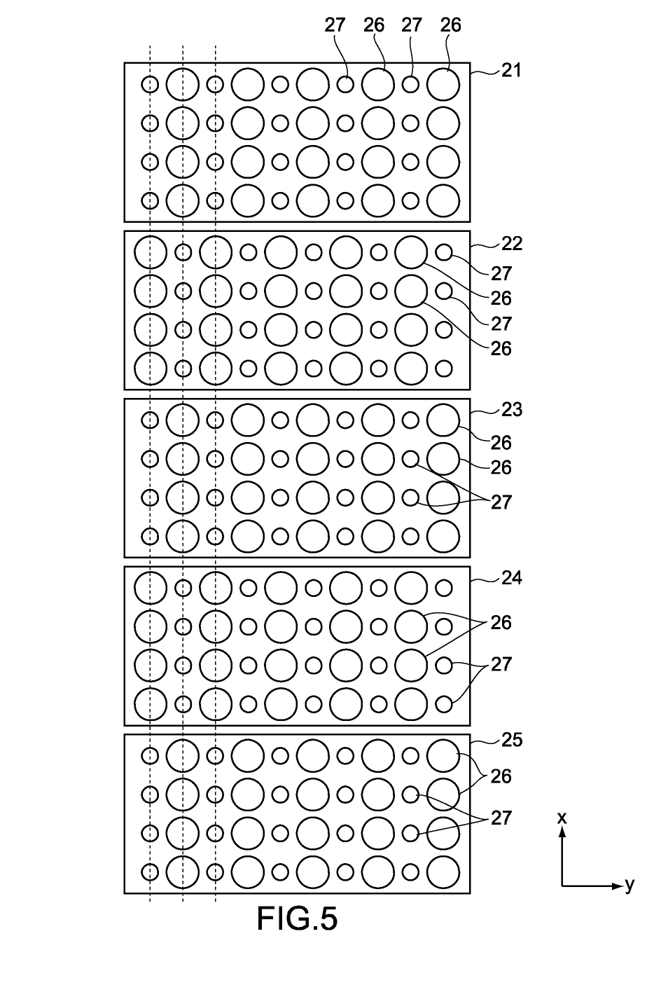

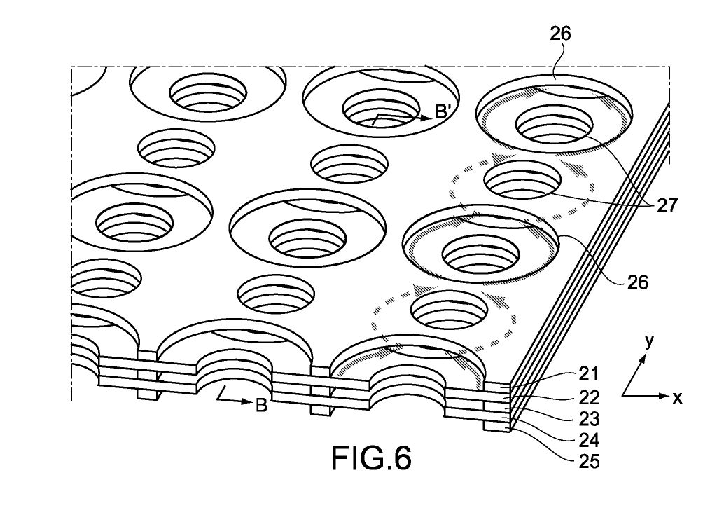

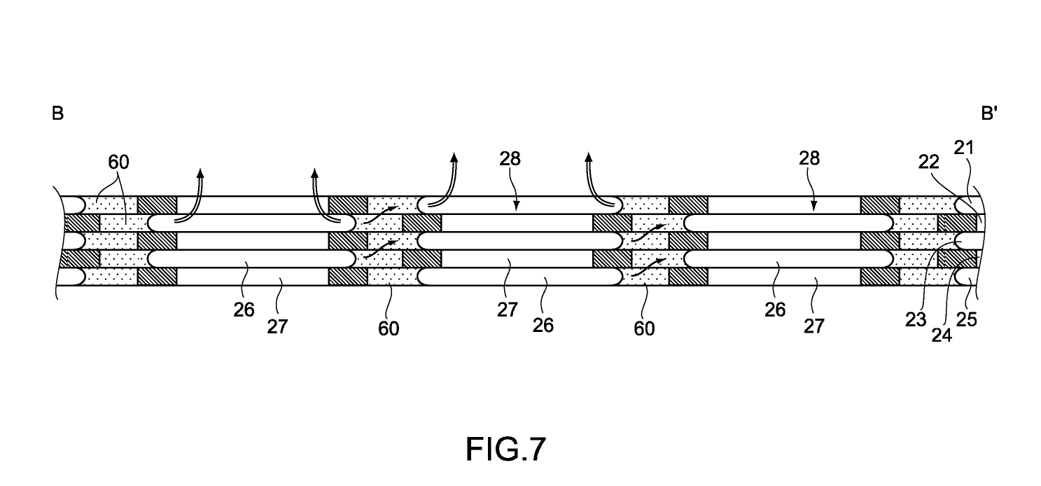

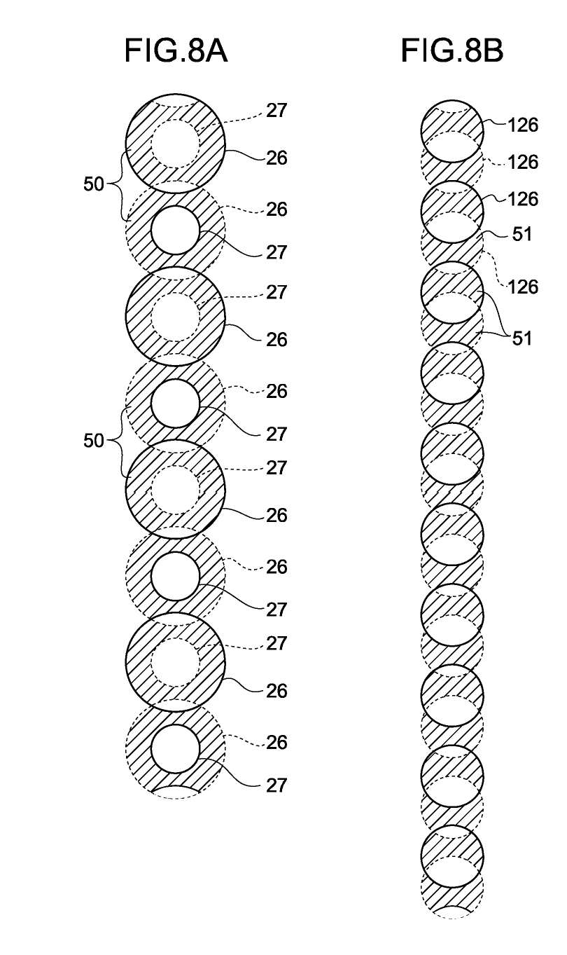

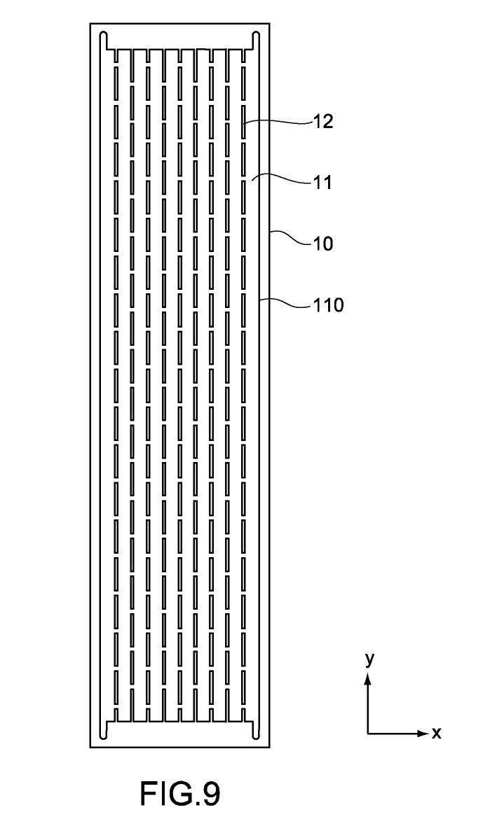

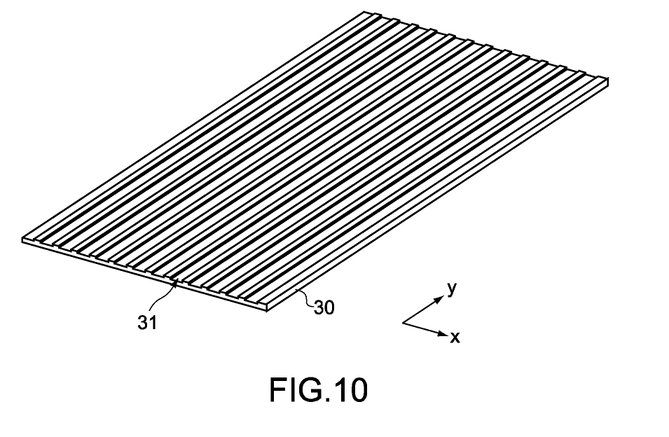

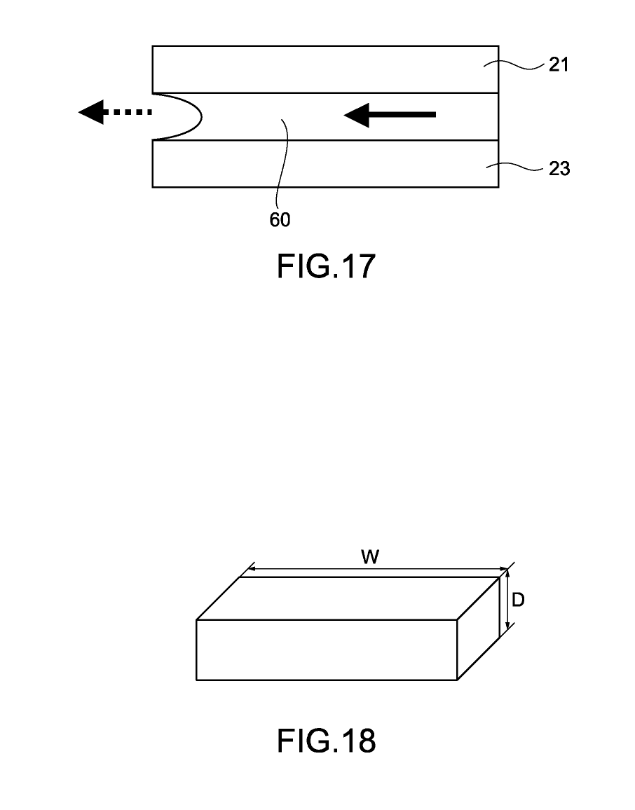

FIG. 1 is an exploded perspective view schematically showing a plate-type heat pipe serving as a heat transport device. FIG. 2 is a schematic diagram for explaining an operation of the heat pipe shown in FIG. 1. FIG. 3 is a plan view schematically showing a thin plate as a plate-like member that constitutes a part of the heat pipe shown in FIG. 1. FIG. 4 is an enlarged plan view showing an area circled by the circle A of FIG. 3. FIG. 5 is a plan view for explaining a positional relationship among holes of a plurality of thin plates layered. FIG. 6 is a partial perspective view of the plurality of thin plates layered. FIG. 7 is a cross-sectional view of the thin plates taken along the line B-B′ of FIG. 6. FIG. 8A is a schematic plan view showing a positional relationship among holes of layered thin plates in this embodiment in which the holes having different sizes are formed. FIG. 8B is a schematic plan view showing a positional relationship among holes in a case where a plurality of thin plates into which the holes having the same size are formed are layered as a comparative example. FIG. 9 is a plan view of an upper plate that constitutes a part of the heat pipe shown in FIG. 1. FIG. 10 is a perspective view of a bottom plate that constitutes a part of the heat pipe shown in FIG. 1. FIG. 17 is a diagram for explaining a capillary structure in this embodiment.

As shown in FIG. 1, a heat pipe 1 in this embodiment is formed by layering a bottom plate 30 as a second outer wall member, thin plates 21 to 25 as five plate-like members, and an upper plate 10 as a first outer wall member in the stated order from the bottom. The bottom plate 30, the thin plates 21 to 25, and the upper plate 10 are the same size, and outlines thereof are rectangle. By bonding outer circumferences of the bottom plate 30, the thin plates 21 to 25, and the upper plate 10, the heat pipe 1 forms an airtight container. In other words, the outline of the airtight container is virtually formed by the bottom plate 30 and the upper plate 10. In the airtight container, the thin plates 21 to 25 sandwiched by the bottom plate 30 and the upper plate 10 are disposed. Examples of a bonding method can include a diffusion bonding, an ultrasonic bonding, and brazing. In this embodiment, the diffusion bonding is used. In the heat pipe 1 as the airtight container, a working fluid (denoted by reference numeral 60 in FIG. 7) is contained. Although detailed structures of the thin plates will be described later, in order to retain a liquid-phase working fluid by an action of a capillary force of the working fluid, first holes and second holes are formed in each of the thin plates 21 to 25. It should be noted that for an actual heat pipe, twenty thin plates are used, for example. In an internal space of the container of the heat pipe 1, a gas-phase portion 90 and a liquid-phase portion 91 are formed. In the gas-phase portion 90, a working fluid vaporized into a liquid phase (vapor) exists in an upper area of the internal space of the container. In the liquid-phase portion 91, a liquid-phase working fluid exists in a lower area thereof.

In this embodiment, dimensions of the heat pipe 1 are 4 cm in width, 16 cm in length, and 0.1 cm in height (i.e., thickness). For each of the bottom plate 30, the thin plates 21 to 25, and the upper plate 10, a material having high heat conductivity such as copper, aluminum, and SUS may be used. In this embodiment, copper is used therefor.

As the working fluid, pure water, alcohol such as ethanol, FC72, or a mixture of pure water and alcohol may be used, for example. In this embodiment, pure water is used.

As shown in FIG. 2, in a case where a heat generation member 40 serving as a heat source is disposed at one end portion of the heat pipe 1, heat generated by the heat generation member 40 is received by a vaporization portion 92, and the working fluid in the liquid-phase portion 91 vaporizes into a vapor. The vapor is moved to the gas-phase portion 90 and further moved to a low-temperature condensation portion 93, and is condensed by the condensation portion 93 into a liquid, thereby releasing heat. As a result, the heat generation member 40 is cooled. The working fluid (denoted by reference numeral 60 in FIG. 7) that has turned into a liquid by the heat radiation by the condensation portion 93 is moved toward the vaporization portion 92 by the capillary force generated by the plurality of thin plates 21 to 25 layered, and is heated again to vaporize. By repeatedly performing those processes, heat can be instantaneously transported from the vaporization portion 92 to the condensation portion 93, which allows heat radiation in a broad range. In an entire operation of the heat pipe 1, the capillary force of the vaporization portion 92 overcomes a flow-path resistance of the gas-phase portion 90, a flow-path resistance of the liquid-phase portion 91, and resistances of the vaporization portion 92 and the condensation portion 93, and operates as a pumping force that circulates the entire heat pipe 1. In this embodiment, the vaporization portion 92 and the condensation portion 93 have the same structure. The vaporization portion 92 has a function of vaporizing the working fluid and receiving heat, and the condensation portion 93 has a function of condensing the vapor into a liquid and releasing the heat.

In this embodiment, by layering the thin plates 21 to 25, a capillary structure is formed. As shown in FIG. 17, by using a narrow space sandwiched by two thin plates, e.g., 21 and 23, the capillary force is generated. A thickness of the narrow space corresponds to a thickness of the thin plate 22 sandwiched by the thin plates 21 and 23. When the working fluid 60 in the narrow space is heated and vaporized, the working fluid 60 moves back along with the vaporization, making a contact angle small (receding contact angle<advancing contact angle). Accordingly, a large capillary force can be generated. In this case, assuming that the space sandwiched by the thin plates is a rectangular parallelepiped having a height D and a width W as shown in FIG. 18, a capillary force Pc can be represented as follows.

Pc=σ cos θ*(D+W)/(D*W) (where σ represents a surface tension and θ represents a contact angle)

In this case, when D<<W is satisfied, the expression can be approximated as follows.

Pc=σ cos θ*D

That is, by reducing the thickness (corresponding to the height D) of the thin plate with flow-path lengths (corresponding to the width W) being the same, a high capillary force can be obtained. In FIG. 17, a solid line indicates a flow of the working fluid and a dotted line indicates a flow of the vapor.

As shown in FIG. 3, the thin plate 21 (22 to 25) is provided with a hole formation area 120. The hole formation area 120 has a rectangular shape and includes protrusions that protrude from four corners thereof. The four protrusions extend in a longitudinal direction of the thin plate 21. In the hole formation area 120, a plurality of first holes 26 and a plurality of second holes 27 having a different size from the first holes 26 are formed.

As shown in FIGS. 4 to 7, in each of the thin plates 21 to 25, the first holes 26 each having a first opening area and the second holes 27 each having a second opening area smaller than the first opening area are formed. In each of the thin plates 21 to 25, the first holes 26 and the second holes 27 are alternately arranged in one direction, specifically, in the longitudinal direction of the thin plate (y-axis direction). The holes of the same size are aligned in an x-axis direction. The first holes 26 and the second holes 27 each have a circular shape. In this embodiment, a diameter of the first hole 26 is set to 0.8 mm and a diameter of the second hole 27 is set to 0.4 mm. Further, a distance between adjacent holes in the longitudinal direction of the thin plate (y-axis direction) is set to 0.1 mm, and a distance between adjacent holes in a direction perpendicular to the longitudinal direction of the thin plate (x-axis direction) is set to 0.1 mm. Furthermore, lines linking the centers of the holes 26 and lines linking the centers of the holes 27 that are aligned in the x-axis direction are parallel to the x-axis direction. Lines linking the centers of the holes 26 and 27 that are aligned in the y-axis direction are parallel to the y-axis direction.

As shown in FIGS. 5 to 7, in this embodiment, the holes having different sizes are alternately provided so that the centers of the holes coincide when the thin plates 21 to 25 layered are viewed in a thickness direction. Specifically, the first hole 26, the second hole 27, the first hole 26, the second hole 27, and the first hole 26 are provided in the stated order from above in the thickness direction of the layered thin plates 21 to 25, or the second hole 27, the first hole 26, the second hole 27, the first hole 26, and the second hole 27 are provided in the stated order from above in the thickness direction thereof. In addition, the first holes 26 arranged in one thin plate in the longitudinal direction thereof are overlapped with the first holes 26 arranged in an adjacent thin plate in the longitudinal direction thereof in a plan view, and the second hole 27 are located within the first holes 26. That is, when two adjacent thin plates out of the layered thin plates 21 to 25 are regarded as a first thin plate and a second thin plate, respectively, the thin plates 21 to 25 are layered in the airtight container so that the first hole 26 of the first thin plate and the first hole 26 of the second thin plate adjacent thereto are communicated with each other, and an opening of the second hole 27 of the second thin plate is located within an opening of the first hole 26 of the first thin plate in order to a vaporized gas-phase working fluid is transferred in the layered direction. In other words, the plurality of thin plates 21 to 25 layered each include the plurality of first holes 26 and the plurality of second holes 27 having the different size from the first holes. The first holes 26 are overlapped with the first holes 26 of the adjacent thin plate in a plan view. Each of the second holes 27 is located within each of the first holes 26 formed in the thin plate adjacent to the thin plate in which the second holes 27 are formed concentrically with the first hole in the plan view thereof.

The thickness of the thin plates 21 to 25 is approximately 5 to 100 μm, for example. The plate thickness corresponds to a capillary size. As described above, thinner the plates, larger the capillary force. However, the gap between the plates is also used for the flow path of the liquid-phase working fluid in this embodiment. Therefore, when the plates are too thin, a flow-path resistance becomes significantly large. For this reason, it is desirable to determine the plate thickness based on a heat transport distance, an amount of heat, and the like. In this embodiment, the plate thickness is set to 20 μm.

In the heat pipe 1, in an area in which a center thin plate, out of three thin plates successively layered, does not exist in a plan view, a space formed by two thin plates that sandwich the center thin plate corresponds to an area 50 in which the capillary force is generated. In other words, in an area in which the thin plates are layered so that the first hole 26 is located between two second holes 27 smaller than the first hole 26 in the thickness direction of the thin plates, in a space formed by the two thin plates in which the second holes 27 are formed, the capillary force is generated. As shown in FIG. 8A, in the heat pipe 1 in this embodiment, a shaded area, that is, an area which is formed by outlines of the plurality of first holes 26 continuously formed and in which the first hole 26 and the second hole 27 are not overlapped and the first holes 26 are not overlapped in a plan view corresponds to the area 50 in which the capillary force is generated. The area 50 in which the capillary force is generated and an area in which two first holes 26 formed in adjacent two thin plates are overlapped in a plan view function as the flow path of the working fluid 60. The working fluid 60 flows through the overlapping portion of the two first holes 26. Accordingly, a plurality of flow paths of the working fluid that are formed by causing the plurality of first holes 26 to be overlapped are provided in the heat pipe 1 in a longitudinal direction thereof (y-axis direction in the figure) on the whole. The working fluid 60 flows along a circumference of the first hole 26 in directions indicated by the solid-line arrows and dotted-line arrows of FIG. 6, and flows upward as indicated by the single-line arrows of FIG. 7. The area where the first holes 26 are overlapped only has to have a width sufficient to secure the flow of the working fluid 60 therein, and the width may be set as appropriate. The gas-phase working fluid 60, namely, vapor passes through holes 28 that are communicated in the thickness direction of the thin plates by the first holes 26 and the second holes 27 and is given out in a direction indicated by the double-line arrows of FIG. 7. In the heat pipe in this embodiment, as shown in FIG. 7, the flow of the working fluid (indicated by the single-line arrow) and the flow of the vapor (indicated by the double-line arrow) coincide. It should be noted that in FIG. 8A, the holes indicated by the solid lines are formed in the thin plates 21, 23, and 25, and the holes indicated by the dotted lines are formed in the thin plates 22 and 24.

As described above, in this embodiment, the plurality of first holes 26 are continuously arranged in the longitudinal direction of the thin plates in the overlapping manner, making it possible to positively secure the flow path of the working fluid along the longitudinal direction of the thin plates. In addition, the second hole 27 is disposed within the first hole 26 in the plan view, thereby forming the through hole 28 that functions as the flow path of the vapor.

Here, in a portion in the area 50 where the capillary force is generated, in which the working fluid 60 is flowed thinly and extensively, a heat transfer of the vapor is large. Therefore, the larger the portion, the larger the heat transfer of the vapor. Accordingly, the heat transport rate of the heat pipe can be improved. In addition, a vaporization efficiency of the working fluid is increased in proportion to an increase in lateral area of the first hole 26 that partly constitutes the through hole 28, and the increase in the vaporization efficiency increases a circulating volume of the working fluid, with the result that heat transport characteristics of the heat pipe can be improved.

For example, in a case where the partition plates each having slits in related art as described above are used, areas where the slits are formed sag, making it difficult to handle the heat pipe. In contrast, in the case where the holes are formed as in this embodiment, the above problem does not arise and the heat pipe is easily handled, which enables stable mass production of the heat pipe.

In this embodiment, the holes having the different sizes are formed in the thin plates. As shown in FIG. 8B, when holes 126 having the same size are formed in the thin plates and the plurality of thin plates are provided so that the holes are overlapped in a plan view, the desirable heat transport characteristics as in this embodiment can hardly be obtained. In the structure shown in FIG. 8, areas where the holes 126 formed in different thin plates are overlapped in the plan view function as through holes through which vapor passes. In order to increase a vaporization quantity, when the overlapping areas of the plurality of holes 126 are set to be large so that a plane area of each through hole is large, it is difficult for the working fluid to flow in the overlapping areas, and the flow path of the working fluid can hardly be obtained in the longitudinal direction of the thin plates. Accordingly, flowing directions of the working fluid and the vapor differ from each other, making it difficult to generate the desired capillary force. On the other hand, when the overlapping areas are set to be small in order to cause the working fluid to flow in the overlapping areas, sufficient vaporization quantity can hardly be obtained. Thus, it is difficult to obtain the structure that provides the desired capillary force and the desired vaporization quantity. In contrast, in this embodiment, the plurality of the first holes 26 are arranged in the overlapping manner in one direction so that the working fluid can flow in the overlapping areas, thereby making it possible to secure the flow path of the working fluid in one direction. As a result, the desired capillary force can be obtained. Further, the second holes 27 are disposed within the first holes 26, thereby making it possible to positively secure the flow path of the vapor through the through holes 28 formed by the first holes 26 and the second holes 27. As a result, the desired vaporization quantity can be obtained. Thus, in the structure according to this embodiment, the heat pipe 1 having excellent heat transport characteristics can be obtained. It should be noted that in FIG. 8B, the holes illustrated by the solid lines indicate holes formed in one thin plate, and the holes illustrated by the dotted lines indicate holes formed in a thin plate adjacent to the one thin plate.

In this embodiment, the upper plate 10 and the bottom plate 30 are provided so as to sandwich the plurality of thin plates in the layered direction of the plurality of thin plates. As shown in FIG. 1, the upper plate 10 has ribs 12 as a plurality of protrusions that protrude toward the inside of the airtight container. As shown in FIG. 9, the upper plate 10 has a rib formation area 110 formed into a rectangular shape. At four corners of the rib formation area 110, protrusions are formed. The four protrusions extend in a longitudinal direction of the upper plate 10. In the rib formation area 110, an area 11 where the ribs 12 are not formed is etched, thereby forming the plurality of ribs 12 each having a plane rectangular shape. The plurality of ribs 12 are formed in the longitudinal direction of the upper plate 10 so that a longitudinal direction of the ribs 12 is parallel to the longitudinal direction (y-axis direction) of the upper plate 10. Further, the ribs 12 are arranged in the longitudinal direction so as not to align with the ribs 12 in adjacent lines. In this embodiment, an etching depth, that is, a height of the rib 12 is set to 0.4 mm, a length of the rib 12 in the longitudinal direction is set to 7.5 mm, a width of the rib 12 in a direction perpendicular to the longitudinal direction of the rib 12 is set to 0.5 mm, a distance between the ribs 12 that are adjacent in the longitudinal direction (y-axis direction) is set to 1 mm, and a distance between the ribs that are adjacent in a direction perpendicular to the longitudinal direction is set to 3.1 mm. Herein, the etching process is used for forming the ribs 12, but other processes such as embossing and electroforming may instead be used.

As described above, the ribs 12 are provided to the upper plate 10, thereby making it possible to obtain the heat pipe 1 having an excellent pressure resistance. Specifically, when the heat pipe 1 is used, an internal pressure is reduced in general. By providing the ribs 12, the heat pipe 1 is prevented from being dented by an external pressure even when the upper plate 10 is thinly formed. In addition, generally, the heat pipe is connected with a heat sink by soldering. In this case, the heat transport device and the heat sink are set into a high-temperature furnace, and solder is melted to connect them in many cases. At this time, a temperature of the heat pipe increases to 200° C. or more in some cases, and a vapor pressure of the working fluid inside the heat pipe becomes significantly high at this time, resulting in applying the pressure from inside toward outside. By providing the ribs 12, the pressure resistance is improved as compared to a case where the ribs 12 are not provided. Here, in the heat pipe 1, the upper plate 10 side corresponds to the gas-phase portion 90. The gas-phase portion 90 is required to transport the vapor from the vaporization portion 92 to the condensation portion 93 with a minimum flow-path resistance of the vapor. Because the flow-path resistance is inversely proportional to the square of a hydraulic diameter (=4*(cross-sectional area/perimeter)), it is necessary to increase the hydraulic diameter as much as possible. In the rectangular shape, the hydraulic diameter is largely affected by a length of short side. Accordingly, there is a limitation to the thickness of the thin heat pipe, and therefore the short side is desired to be as long as possible within the limitation of the thickness of the heat pipe. To make the heat pipe thin, the thickness of the upper plate may be reduced. In this case, however, when the upper plate has a flat surface, the upper plate is dented by the external pressure. In contrast, by providing the ribs 12 as in this embodiment, the pressure resistance can be improved, and the heat pipe can be further thinned.

Further, in this embodiment, the capillary structure is formed by the ribs 12 of the upper plate 10 and the thin plate 21 adjacent to the upper plate 10, and thus the flow-path resistance of the vapor can be reduced.

As shown in FIGS. 1 and 10, the bottom plate 30 has a plurality of linear grooves 31 in the longitudinal direction as one direction (y-axis direction) on a surface thereof on a side of the thin plate. With this structure, the flow-path resistance of the liquid-phase working fluid can be reduced, and thus the amount of heat transport can be secured even in the heat pipe for long-distance transport like the thin heat pipe.

In the case where the heat transport distance is long like the thin heat pipe, the flow-path resistances of the liquid-phase and gas-phase working fluid become large. Therefore, the sufficient amount of heat transport is difficult to be obtained unless the capillary force is further increased. However, to increase the capillary force, it may be necessary to form a microstructure. Accordingly, as in this embodiment, in the case where the area in which the capillary force is generated in the thin plates, and the flow path of the liquid-phase working fluid is formed by the thin plates, when the capillary force is to be increased, the flow-path resistance becomes significantly large, which may require reduction in flow-path resistance of the liquid-phase working fluid. In view of this, in this embodiment, by forming the grooves 31 in the bottom plate 30, the flow-path resistance of the liquid-phase working fluid can be reduced.

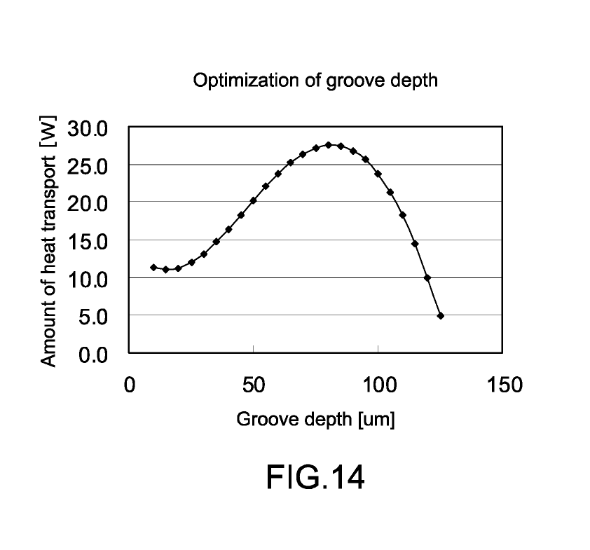

In this embodiment, a depth of the groove 31 is set to 80 μm, a distance between adjacent grooves 31 is set to 200 μm, and a width of the groove 31 in the x-axis direction is set to 400 μm. FIG. 14 is a graph plotted by calculating a heat transport amount L with the groove thickness changed in a case where the groove width and the distance between the grooves are fixed to the above-mentioned values, the size and structure of the thin plates are the same as the structure in this embodiment, the number of thin plates is set to 20, and the flow-path resistance per volume flow of the gas-phase working fluid is set to be 4.7*10¹⁰ Pa·sec/m³. When the grooves are not formed, the heat transport amount of only about 10 W can be obtained. As shown in FIG. 14, by setting the depth of the groove 31 to 80 μm, heat of about 27 W can be transported. It is desirable to set the depth of the groove 31 to 50 to 100 μm. With this setting, large heat transport amount L can be obtained.

The heat transport amount L (W) is obtained by multiplying a flow rate Q by latent heat of pure water as the working fluid. As the flow rate Q, a flow rate at the time when a value of the capillary force generated by the grooves 31 is the same as a value of the flow-path resistance of the flow path formed by the grooves 31 is used. The flow rate Q is proportional to a flow-path resistance R and is therefore obtained by calculating the flow-path resistance R. The flow-path resistance R and the capillary force are obtained by using the following expression.

The flow-path resistance R (Pa·sec/m³) of the rectangular flow path is obtained as follows.

R=12μ·func(D/W)·L/D²(DW)

where,
μ: dynamic viscosity of liquid (Pa·sec)
D: width (m) of a narrow side of the rectangular flow path, which corresponds to the groove depth of the bottom plate
W: width (m) of a broad side of the rectangular flow path, which corresponds to the groove width of the bottom plate
L: transport distance (m)
func(D/W): function determined by D/W

Based on the above expression, a flow-path resistance of a composite flow path is obtained. The flow-path resistance of the composite flow path can be estimated if respective flow paths that constitute the composite flow path can be obtained, and is obtained as follows.

Regarding the flow-path resistance of the liquid-phase working fluid, in terms of the calculation and experiment, it was confirmed that the resistance of a single flow path and the resistance of the composite flow path have the following relationship.

In a case where a pressure loss ΔP (Pa), the volume flow Q (m³/sec), and the flow-path resistance R (Pa·sec/m³) are defined, those relationship can be expressed as follows.

ΔP=R*Q

Here, when a flow path 1 and a flow path 2 which are parallel to each other and through which the fluid therein can be transferred between them are provided, if the same pressure loss AP is received, relationships between flow-path resistances R1 and R2 of the flow paths 1 and 2 and volume flows Q1 and Q2 thereof can be expressed as follows.

ΔP=R1*Q1=R2*Q2, Q=Q1+Q2

When Q1 and Q2 are deleted from those expressions, the following expression can be obtained.

1/R=1/R1+1/R2

That is, if the flow-path resistances of the respective flow paths can be obtained, the flow-path resistance of the composite flow path can be estimated. The flow-path resistances of the respective flow paths can be obtained by forming the flow paths. Further, various calculation methods of the flow-path resistances are described in “Heat Pipe Science and Technology”.

On the other hand, the capillary force can be obtained from the surface tension generated in a vicinity of a perimeter of a capillary and an area of a surface on which the surface tension is applied. Regarding the capillary force of the rectangular flow path having a cross section of D*W (D: width (m) of the narrow side of the rectangular flow path, which corresponds to the groove depth of the bottom plate, W: width (m) of the broad side of the rectangular flow path, which corresponds to the groove width of the bottom plate), the perimeter is 2(D+W), so the surface tension (N) generated thereon is 2(D+W)·σ·cos θ (where, σ represents the surface tension (N/m) and θ represents a contact angle). Accordingly, the area of the rectangular cross section is D·W, and therefore the capillary force Pc is expressed as follows.

Pc=2(D+W)·σ·cos θ/(D·W) (N/m²)

Here, in the case where the composite flow path is provided, the surface tension on the entire perimeter in which the capillary force can be generated is applied to the entire area of the composite flow path. Therefore, when flow-path lengths L1 and L2 and flow-path areas A1 and A2 are given, the entire capillary force can be expressed by (L1+L2)·σ·cos θ/(A1+A2), and the capillary force is obtained by using an expression for calculating the capillary force of the composite flow path.

As described above, in this embodiment, by forming in the thin plates the plurality of holes having different sizes, large capillary force is maintained. Further, by forming the grooves in the bottom plate, the flow-path resistance of the liquid-phase working fluid can be reduced.

For forming the first holes 26 and the second holes 27 in the thin plates 21 to 25, it is possible to apply a holing process by punching using a pin to a mold on a side on which holes are punched. In this case, the pin can be easily processed, and the pin can be easily repaired when broken. Further, it is unnecessary to consider a rotation direction of the pin when the pin and a table on a side to which the pin is put are aligned. Accordingly, the alignment can be easily carried out. Therefore, the manufacturing cost can be significantly reduced as compared to the case where the slits are formed, and the heat pipe having excellent heat transport characteristics can be stably mass-produced. Further, instead of the holing process by punching, an etching process or the like can be applied to form the hole.

In the above embodiment, the first holes 26 and the second holes 27 having the different size from the first holes are formed in one thin plate. Alternatively, as a modified example, only holes having the same size may be formed in one thin plate.

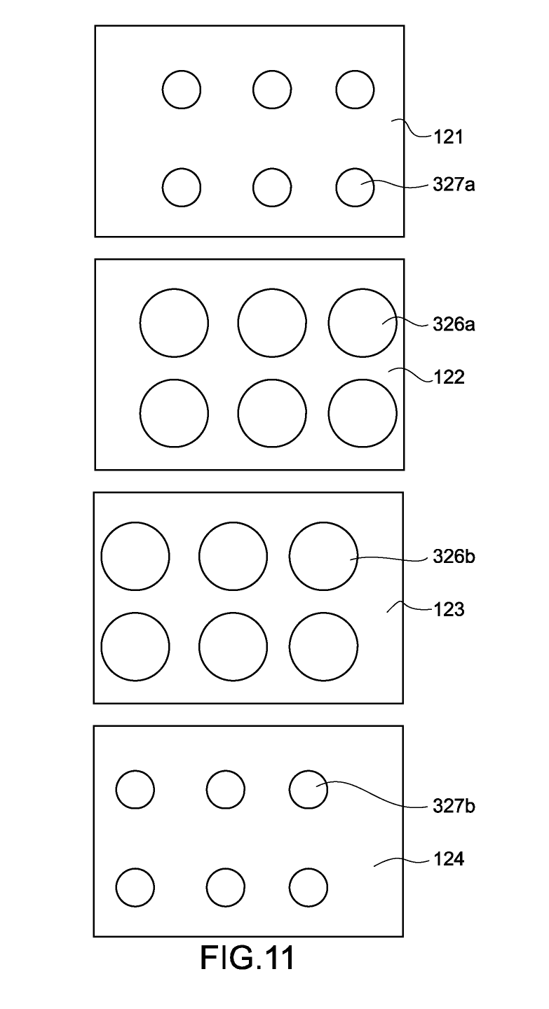

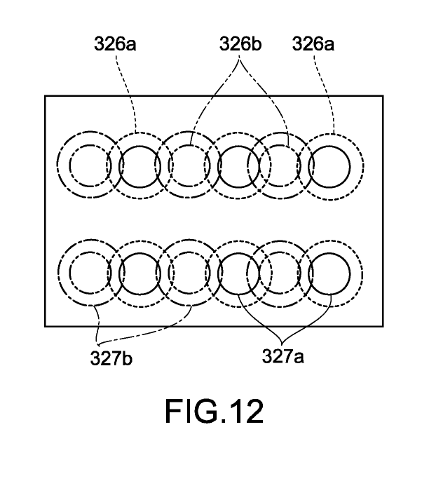

FIG. 11 is a schematic plan view showing shapes of, e.g., four thin plates used. FIG. 12 is a diagram showing a positional relationship among holes when the four thin plates shown in FIG. 11 are layered.

As shown in FIGS. 11 and 12, first holes 326a and 326b having the same first opening area are formed in a second thin plate 122 and a third thin plate 123 as a first plate-like member, respectively. Second holes 327a and 327b each having a second opening area that is smaller than the first opening area are formed in a first thin plate 121 and a fourth thin plate 124 as a second plate-like member, respectively. The second holes 327a of the first thin plate 121 and the first holes 326a of the second thin plate 122 are concentric in a plan view when the plates are layered. The first holes 326b of the third thin plate 123 and the second holes 327b of the fourth thin plate 124 are concentric in a plan view when the plates are layered. The first holes 326a of the second thin plate 122 and the first holes 326b of the third thin plate 123 are overlapped when the thin plates are layered in a plan view. In other words, the first holes 326a of the thin plate 122 as the first plate-like member and the first holes 326b of the thin plates 123 as the first plate-like member adjacent to the above first plate-like member form through holes. In addition, in order to cause the gas-phase working fluid vaporized to flow in a layered direction, the thin plates 121 to 124 are layered so that openings of the second holes 327a and 327b of the thin plates 121 and 124 as the second plate-like member are located within openings of the first holes 326a and 326b of the thin plates 122 and 123 as the first plate-like member. In other words, the plurality of layered thin plates 121 to 124 have the plurality of first holes 326a and 326b and the plurality of second holes 327a and 327b, respectively. The first holes 326a and 326b have the size different from the second holes 327a and 327b. The first holes 326a and 326b are overlapped with the holes formed in the adjacent thin plates in a plan view. The second holes 327a and 327b are formed within the first holes formed in the thin plates adjacent to the thin plates where the second holes 327a and 327b are formed in a concentric manner in a plan view. A width of an area in which the first hole 326a and the second hole 326b are overlapped may be set so that the area functions as the flow path through which the working fluid flows. In this way, by forming the first holes and the second holes in the thin plates 121 to 124, the capillary force is operated for the liquid-phase working fluid, thereby retaining the working fluid between the thin plates.

In the above-described structure, as in the above embodiment, by continuously forming the plurality of first holes 326a and 326b in the thin plates in the longitudinal direction in the overlapping manner, the flow path of the working fluid in the longitudinal direction of the thin plates can also be secured. In addition, by forming the second holes 327a and 327b so as to be located within the first holes 326a and 326b in the plan view, the through holes formed by those holes function as the flow path of the vapor. Further, the area where the capillary force is generated can be formed into a shape like a plurality of continuous circular arcs.

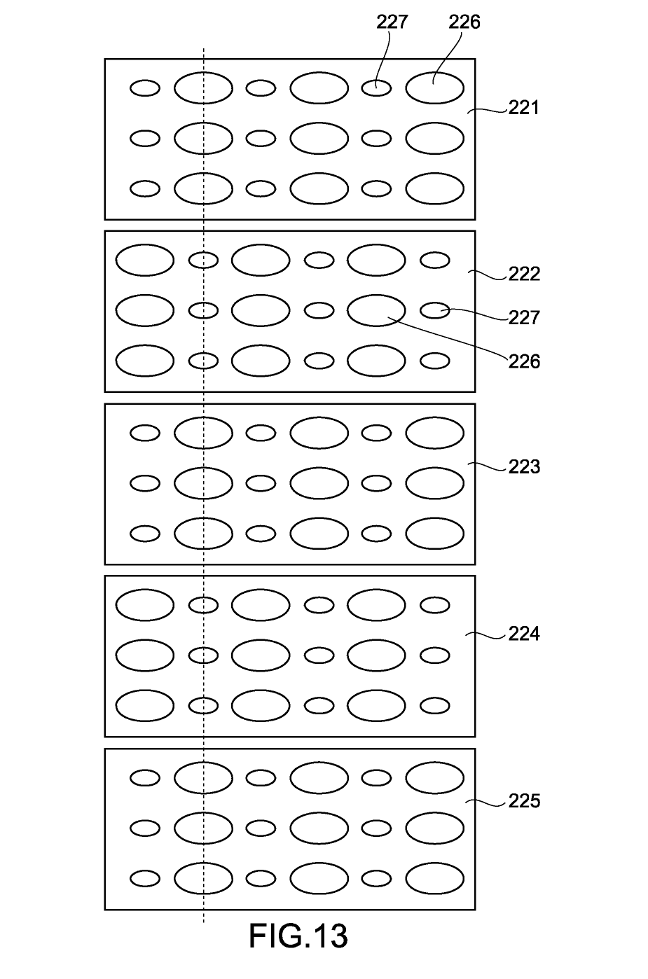

In the above embodiment, the holes have a circular shape. Alternatively, the holes may have an oval shape as shown in FIG. 13 or a rectangular shape, but the shape thereof is not limited thereto. Further, as in the modified example described with reference to FIG. 11, only the holes having the same size may be formed in one thin plate.

FIG. 13 is a schematic plan view showing shapes of, e.g., five thin plates used.

As shown in FIG. 13, in thin plates 221 to 225, first holes 226 and second holes 227 are alternately aligned in one direction. The first holes 226 each have different sizes from the second holes 227. In a direction perpendicular to the one direction, the holes having the same size are aligned. The first holes 226 and the second holes 227 each have an oval shape having a longitudinal direction in the one direction. Further, a line linking centers of the holes 226 and 227 aligned in a direction perpendicular to the one direction is parallel to the direction perpendicular to the one direction, and a line linking the centers of the holes 226 and 227 aligned in the one direction is parallel to the one direction.

When viewed in a thickness direction of the thin plates 221 to 225, the holes having the different sizes are alternately formed so that the centers of the oval holes coincide in a plan view in an order of the first hole 226, the second hole 227, the first hole 226, the second hole 227, and the first hole 226, or in an order of the second hole 227, the first hole 226, the second hole 227, the first hole 226, and the second hole 227 from above. In addition, the first holes 226 of one thin plate are overlapped with the first holes 226 of adjacent thin plate in the longitudinal direction of the thin plates in the plan view, and the second hole 227 is located within the first hole 226. That is, the plurality of layered thin plates 221 to 225 each have the plurality of first holes 226 and the plurality of second holes 227, the first holes 226 are overlapped with the first holes formed in the adjacent thin plate in the plan view, and the second holes 227 are located within the first holes 226 formed in the thin plate adjacent to the thin plate where this second holes 227 are formed in the plan view.

In the structure as described above, as in the above embodiment, by continuously forming the plurality of first holes 226 in the thin plates the longitudinal direction in the overlapping manner, the flow path of the working fluid in the longitudinal direction of the thin plates can be secured. Further, by disposing the second holes 227 within the first holes 226 in the plan view, through holes formed by the first and second holes function as the flow path of the vapor. Furthermore, the area where the capillary force is generated can be formed into a shape like a plurality of continuous circular arcs.

In addition, the description is given above on the operation of the heat pipe 1 in the above embodiment with the heat generation member being disposed on the liquid-phase working fluid side as shown in FIG. 2. Alternatively, when the heat generation member is disposed on the gas-phase working fluid side, the same effect can also be obtained. This may be because the heat pipe 1 is very thin.

(Electronic Apparatus)

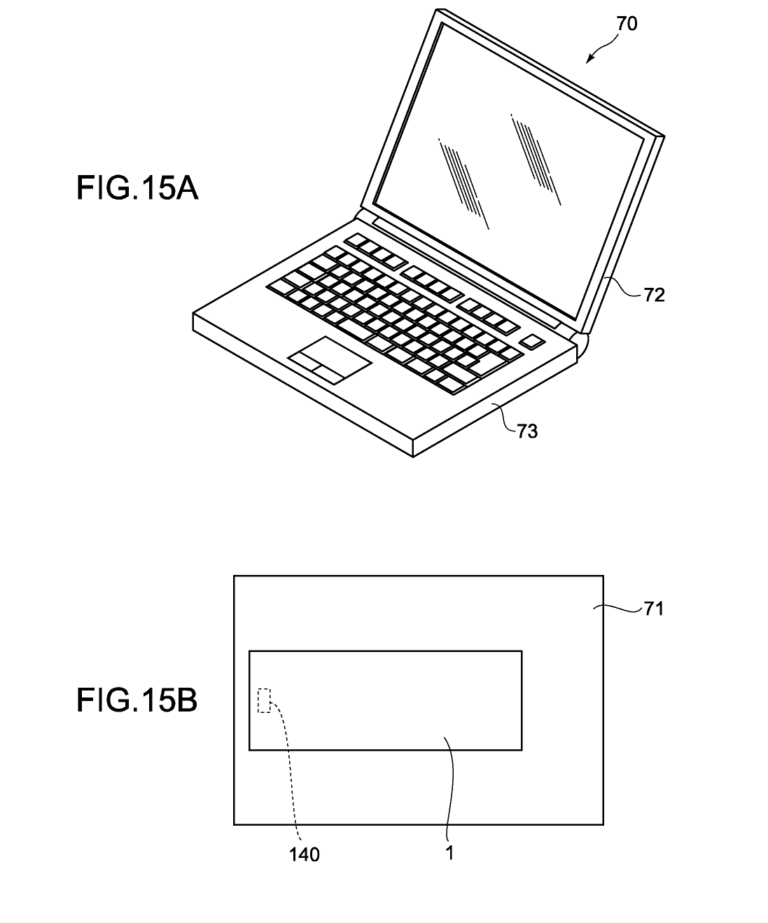

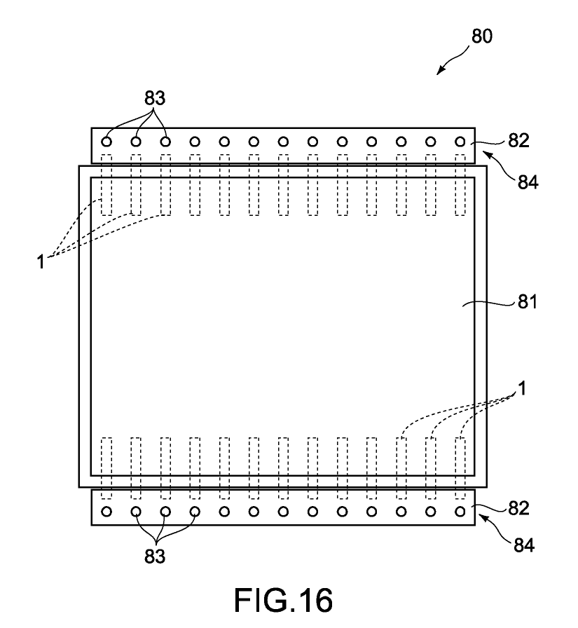

A description will be given on a liquid crystal television and a personal computer as electronic apparatuses using the heat pipe according to the above embodiment with reference to FIGS. 15 and 16.

FIG. 15A is a schematic perspective view of a personal computer, and FIG. 15B is a schematic plan view of a component incorporated in the personal computer shown in FIG. 15A. FIG. 16 is a schematic plan view of a liquid crystal television.

As shown in FIGS. 15A and 15B, a personal computer 70 includes a keyboard portion 73 on which various keys are provided and a liquid crystal display portion 72. In the keyboard portion 73, on a chassis 71 made of aluminum or the like as a base, input keys, a control circuit substrate for controlling a display of the liquid crystal display portion 72, and the like are provided. On the control circuit substrate, a CPU (Central Processing Unit) 140 that is an electronic circuit component serving as a heat generation member is mounted. In this embodiment, the heat pipe 1 is disposed adjacently to the CPU 140. With this structure, heat generated in the CPU 140 is quickly transported through the heat pipe 1, which can set a temperature of the chassis 71 to be uniform in plane and can radiate heat. In this way, in this embodiment, because the heat pipe 1 is thin, reduction in thickness of the personal computer 70 can be realized. In addition, a fan serving as a heat radiation component can be eliminated, and therefore further reduction in thickness and weight can be realized. It should be noted that in this embodiment, a planner outline of the heat pipe 1 is smaller than that of the chassis 71, but may be set to be the same. Further, a heat sink may be used so that the heat pipe 1 is adjacent to the heat sink, but is not limited to this structure.

As shown in FIG. 16, a liquid crystal television 80 includes a liquid crystal display portion 81 and a back light 84 of an edge light type for irradiating the liquid crystal display portion 81 with light. The back light 84 is disposed on each of opposed upper and lower sides of the rectangular liquid crystal display portion 81. The back light 84 is structured by disposing a plurality of white LEDs 83 on a copper plate 82. In this embodiment, a plurality of heat pipes 1 are connected to the copper plate 82. With this structure, heat generated from the white LEDs 83 is extensively transmitted to the entire liquid crystal television 80 by the heat pipes 1, and a temperature can be set to be approximately uniform in plane to radiate heat. Thus, a burn at a low temperature can be prevented, for example. Further, in this embodiment, because the heat pipe 1 is thin, reduction in thickness of the liquid crystal television 80 can be realized.

As described above, by providing the heat pipe 1 described above to the electronic apparatus including the heat generation member, heat generated from the heat generation member can be extensively transmitted. Thus, a temperature difference is caused between the heat pipe 1 and air, and heat transfer occurs therebetween, with the result that heat can be quickly radiated.

The present application contains subject matter related to that disclosed in Japanese Priority Patent Application JP 2008-165352 filed in the Japan Patent Office on Jun. 25, 2008, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A heat transport device, comprising:
an airtight container;
a working fluid contained in the airtight container; and
a plurality of plate-like members including a first plate-like member and a second plate-like member adjacent to the first plate-like member, the plurality of plate-like members each having a first hole having a first opening area and a second hole having a second opening area smaller than the first opening area, the plurality of plate-like members being layered in the airtight container so that the first hole of the first plate-like member and the first hole of the second plate-like member are communicated with each other, to retain the working fluid in a liquid phase by applying a capillary force to the working fluid, and so that an opening of the second hole of the second plate-like member is located within an opening of the first hole of the first plate-like member, to transfer the working fluid vaporized into a gas phase in the layered direction.

2. The heat transport device according to claim 1, further comprising:
a bottom plate and an upper plate that constitute the airtight container and are provided to sandwich the plurality of plate-like members,
wherein the upper plate having a protrusion that protrudes toward the plurality of plate-like members.

3. The heat transport device according to claim 2,
wherein the bottom plate has a groove on a surface on a side on which the plurality of plate-like members are provided.

4. A heat transport device, comprising:
an airtight container;
a working fluid contained in the airtight container; and
a plurality of plate-like members including first plate-like members each having a first hole having a first opening area and second plate-like members each having a second hole having a second opening area smaller than the first opening area, the plurality of plate-like members being layered in the airtight container so that the first holes of the first plate-like members adjacent to each other are communicated with each other, to retain the working fluid in a liquid phase by applying a capillary force to the working fluid, and so that an opening of the second hole of each of the second plate-like members is located within an opening of the first hole of each of the first plate-like members, to transfer the working fluid vaporized into a gas phase in the layered direction.

5. A heat transport device, comprising:
a working fluid;
a plurality of plate-like members including a first plate-like member and a second plate-like member adjacent to the first plate-like member, the plurality of plate-like members each having a first hole having a first opening area and a second hole having a second opening area smaller than the first opening area, the plurality of plate-like members being layered in the airtight container so that the first hole of the first plate-like member and the first hole of the second plate-like member are communicated with each other, to retain the working fluid in a liquid phase by applying a capillary force to the working fluid, and so that an opening of the second hole of the second plate-like member is located within an opening of the first hole of the first plate-like member, to transfer the working fluid vaporized into a gas phase in the layered direction; and
a first outer wall member and a second outer wall member that are provided to sandwich the plurality of plate-like members in the layered direction of the plurality of plate-like members.

6. A heat transport device, comprising:
a working fluid;
a plurality of plate-like members including first plate-like members each having a first hole having a first opening area and second plate-like members each having a second hole having a second opening area smaller than the first opening area, the plurality of plate-like members being layered so that the first holes of the first plate-like members adjacent to each other are communicated with each other, to retain the working fluid in a liquid phase by applying a capillary force to the working fluid, and so that an opening of the second hole of each of the second plate-like members is located within an opening of the first hole of each of the first plate-like members, to transfer the working fluid vaporized into a gas phase in the layered direction; and
a first outer wall member and a second outer wall member that are provided to sandwich the plurality of plate-like members in the layered direction of the plurality of plate-like members.

7. An electronic apparatus, comprising:
a heat generation member; and
a heat transport device disposed adjacently to the heat generation member, the heat transport device including an airtight container, a working fluid contained in the airtight container, and a plurality of plate-like members including a first plate-like member and a second plate-like member adjacent to the first plate-like member, the plurality of plate-like members each having a first hole having a first opening area and a second hole having a second opening area smaller than the first opening area, the plurality of plate-like members being layered in the airtight container so that the first hole of the first plate-like member and the first hole of the second plate-like member are communicated with each other, to retain the working fluid in a liquid phase by applying a capillary force to the working fluid, and so that an opening of the second hole of the second plate-like member is located within an opening of the first hole of the first plate-like member, to transfer the working fluid vaporized into a gas phase in the layered direction.
